(19) United States
(12) Patent Application Publication
(10) Pub. No.: US 2007/0281372 A1
(43) Pub. Date: Dec. 6, 2007

(54) MEMORY ELEMENT, METHOD FOR MANUFACTURING MEMORY ELEMENT, MEMORY DEVICE, ELECTRONIC APPARATUS AND METHOD FOR MANUFACTURING TRANSISTOR

(75) Inventors: Hiroshi TAKIGUCHI, Suwa-shi (JP); Junichi KARASAWA, Shimosuwa-machi (JP)

Correspondence Address: OLIFF & BERRIDGE, PLC, P.O. BOX 19928, ALEXANDRIA, VA, 22320, US

(73) Assignee: SEIKO EPSON CORPORATION, Tokyo (JP)

(21) Appl. No.: 11/747,653

(22) Filed: May 11, 2007

(30) Foreign Application Priority Data
Jun. 5, 2006 (JP) 2006-156380

(51) Int. Cl. H01L 21/00; H01L 21/8238; H01L 21/8242

(52) U.S. Cl. 438/3; 438/240; 438/216; 257/E27.104

(57) ABSTRACT

A method for manufacturing a memory element including forming a first electrode on a first face of a substrate; forming a ferroelectric layer on a second face of the first electrode, the second face being on an opposite side to the substrate side, and the ferroelectric layer being mainly made of a crystalline organic ferroelectric material; and forming a second electrode on a third face of the ferroelectric layer, the third face being on an opposite side to the first electrode side, the second electrode being formed by ejecting an vaporized electrode material in a direction inclined with respect to a normal line direction of the substrate and depositing the vaporized electrode material on the third face of the ferroelectric layer, wherein data writing/reading is performed by changing a polarized state of the ferroelectric layer by applying a voltage between the first electrode and the second electrode.

### BACKGROUND OF THE INVENTION

1. Technical Field

Several aspects of the present invention relate to a memory element, a method for manufacturing a memory element, a memory device, an electronic apparatus and a method for manufacturing a transistor.

2. Related Art

A memory element made of ferroelectric material has been known. In the memory element, an electric field is applied to a ferroelectric layer made of the ferroelectric material in its thickness direction. This elemenet changes its polarized state and in this way writing and reading of data is performed. The polarized state in the ferroelectric layer is bistable and retained even after the application of the electric field has stopped thereby such memory element can be used as a nonvolatile memory.

Use of an organic ferroelectric material has been recently proposed as the ferroelectric material forming such memory element in order to make the memory element flexible. Journal of Applied Physics, Vol. 89, No. 5, pp. 2613-16 is an example of related art. The example discloses crystalline organic ferroelectric materials which can be used as the organic ferroelectric material and with which quality of the memory can be improved.

When the ferroelectric layer is formed by using such organic ferroelectric material, a method in which a liquid phase thin film forming process such as spin coat methods using a liquid that contains the organic ferroelectric material and a crystallization process are combined is preferred to a gas phase thin film forming process such as evaporation methods with which a degree of the crystallinity cannot be easily controlled. The method combining the liquid phase thin film forming process and the crystallization process has advantages in terms of freedom of choice in material and process costs.

More specifically, according to a hitherto known method, a ferroelectric layer is formed by applying the liquid on a lower electrode and then drying and crystallizing the applied liquid. An upper electrode is subsequently formed on the ferroelectric layer by a gas phase film forming method. According to such method using the liquid material, the ferroelectric layer can be formed without using large vacuum equipment, which will be required in the gas phase thin film forming process. Moreover, the layer can be formed under the conditions almost equal to a room temperature and a normal pressure according to the method using the liquid material. Therefore, it is possible to reduce the energy and the cost which are required to fabricate the organic ferroelectric capacitor.

However, the ferroelectric layer formed according to the above-described way tends to have a rough surface, which is the face opposite to the lower electrode. This roughness is made by large crystal grains, which are formed during the crystallization process of the organic ferroelectric layer. This phenomenon occurs in the thin film formed by either the gas phase method or in the thin film formed by the liquid phase method. Accordingly, where the ferroelectric layer having the thickness about the size of the crystal grain is formed according to an hitherto known manufacturing method for an memory element, an electrode forming material flows into concave portions in the rough surface of the ferroelectric layer when the upper electrode is formed. This narrows the gaps between the upper electrode and the lower electrode locally and the two electrodes could face too close or contact each other, which could increase the flow of leakage current and could cause a short circuit between the upper electrode and the lower electrode. The degree of the above-mentioned roughness in the ferroelectric layer do not largely change even though the thickness of the ferroelectric layer differs, therefore the thicker the ferroelectric layer becomes, the more adverse affects become prominent.

The organic ferroelectric layers made of a copolymer of vinylidene fluoride and trifluoroethylene or a polymer of vinylidene fluoride generally have a very high coercive electric field so that the thickness of such organic ferroelectric thin film has to be extremely thin in order to lower the driving voltage. However, it has been difficult to make the ferroelectric layer extremely thin for the above-mentioned reasons. It was also very difficult to lower the driving voltage of the memory element by forming a thin ferroelectric layer.

### SUMMARY

An advantage of the present invention is to provide a method for manufacturing a memory element having a ferroelectric layer made of a crystalline organic ferroelectric material with which a driving voltage can be lowered, a memory element, a memory device and an electronic apparatus thereof. Another advantage of the invention is to provide a method for manufacturing a transistor having an insulating layer made of a crystalline organic ferroelectric material with which a driving voltage can be lowered.

A method for manufacturing a memory element according to a first aspect of the invention includes forming a first electrode on a first face of a substrate; forming a ferroelectric layer on a second face of the first electrode, the second face being on an opposite side to the substrate side, and the ferroelectric layer being mainly made of a crystalline organic ferroelectric material; and forming a second electrode on a third face of the ferroelectric layer, the third face being on an opposite side to the first electrode side, the second electrode being formed by ejecting an vaporized electrode material in a direction inclined with respect to a normal line direction of the substrate and depositing the vaporized electrode material on the third face of the ferroelectric layer, wherein data writing/reading is performed by changing a polarized state of the ferroelectric layer by applying a voltage between the first electrode and the second electrode.

According to the first aspect of the invention, even though a rough face made by the crystal grains of the organic ferroelectric material is formed on the side of the ferroelectric layer where the second electrode is to be formed, it is possible to prevent or stop the electrode material from entering into the concave portions of the rough face when the second electrode is formed. Moreover, it is possible to prevent gaps between the first electrode and the second electrode from becoming small in some place. Consequently, this prevents the increase of leakage current and a short circuit between the first electrode and the second electrode even though the ferroelectric layer is made thin. It follows that the ferroelectric layer can be made thinner, which makes it possible to lower the driving voltage.

A method for manufacturing a memory element according to a second aspect of the invention includes forming a pair of first electrodes with a predetermined space therebetween on a substrate; forming a semiconductor layer such that the semiconductor layer contacts with both of the first electrodes; forming a ferroelectric layer on a first face of the semiconductor layer, the first face being on an opposite side to the substrate side, and the ferroelectric layer being mainly made of a crystalline organic ferroelectric material; forming a second electrode on a second face of the ferroelectric layer, the second face being on an opposite side to the semiconductor layer side, the second electrode being formed by ejecting an vaporized electrode material in a direction inclined with respect to a normal line direction of the substrate and depositing the vaporized electrode material on the second face of the ferroelectric layer, and wherein data writing/reading is performed by changing a polarized state of the ferroelectric layer by applying a voltage between the first electrode and the second electrode.

According to the second aspect of the invention, even though a rough face made by the crystal grains of the organic ferroelectric material is formed on the side of the ferroelectric layer where the second electrode is to be formed, it is possible to prevent or stop the electrode material from entering into the concave portions of the rough face when the second electrode is formed. Moreover, it is possible to prevent gaps between the first electrode and the second electrode from becoming small in some place. Consequently, this prevents the increase of leakage current and a short circuit between the first electrode and the second electrode even though the ferroelectric layer is made thin. It follows that the ferroelectric layer can be made thinner, which makes it possible to lower the driving voltage.

In this case, it is preferable that an angle θ between the ejecting direction of the vaporized electrode material and the normal line direction of the substrate around the ferroelectric layer be 20-70°.

In this way, even though a rough face made by the crystal grains of the organic ferroelectric material is formed on the side of the ferroelectric layer where the second electrode is to be formed, it is possible to securely prevent or stop the electrode material from entering into the concave portions of the rough face when the second electrode is formed.

It is also preferable that the substrate be held by a substrate holder from an opposite side to the first face side in such a way that the substrate is inclined with respect to a material source that ejects the vaporized electrode material while the electrode material be ejected from the material source toward the ferroelectric layer formed over the substrate so as to form the second electrode.

In this way, the vaporized electrode material can be ejected in the inclined direction with respect to the normal line direction of the substrate with such relatively simple structure.

It is preferable that the substrate holder rotate or move around on an axis that extends in a thickness direction of the substrate which is held by the substrate holder. With such structure, it is possible to prevent unevenness in the electrode material deposition depending on a position on the substrate and to obtain the second electrode with a uniform thickness and a uniform film quality.

In this case, it is preferable that the substrate holder hold a plurality of substrates. In this way, the plurality of the substrates can be simultaneously processed and the second electrode can be formed on each of the substrates.

In this case, it is preferable that the substrate holder hold the plurality of the substrates in a same plane which is orthogonal to the axis of the substrate holder and each of the substrates is placed at a same distance from the axis. In this way, it is possible to prevent unevenness in the electrode material deposition among the substrates and to obtain the second electrode with a uniform thickness and a uniform film quality on each of the substrates.

It is also preferable that the substrate holder rotate or move each of the substrates around on an axis line that extends from a center of each substrate in a thickness direction of each substrate. In this way, it is possible to prevent unevenness in the electrode material deposition among the substrates and unevenness in the electrode material depending on a position on the substrate.

It is preferable that a slit plate having an opening of a slit shape be interposed between the material source and the substrate, the substrate be moved in a shorter direction of the opening of the slit plate while the vaporized electrode material that goes through the opening of the slit plate be deposited on the substrate so as to form the second electrode. With such structure, it is possible to prevent unevenness in the electrode material deposition depending on a position on the substrate and to obtain the second electrode with a uniform thickness and a uniform film quality.

The forming process of the ferroelectric layer in the above-described manufacturing methods may further include forming a low-crystalline film having a lower crystallinity than a crystallinity of the finished ferroelectric layer by applying a liquid material containing the organic ferroelectric material on the first electrode and drying the applied liquid material, and heating the low-crystalline film so as to increase the crystallinity thereof and to form the ferroelectric layer.

In this way, the organic ferroelectric material can be in a fluid form during the period from the application of the liquid material to the crystallization. This makes it relatively easy to control the degree of the crystallinity of the ferroelectric layer 4 and to have a desired crystallinity.

It is preferable that the ferroelectric layer have a rough surface on the face where the second electrode is to be formed, the rough surface be made by crystal grains of the organic ferroelectric material, and the ejecting direction of the vaporized electrode material be slanted with respect to the normal direction of the substrate so as to stop or prevent the electrode material from entering into concave portions of the rough surface.

In this way, it is possible to prevent gaps between the first electrode and the second electrode from becoming small in some place.

A memory element according to a third aspect of the invention is manufactured by any of the above mentioned methods.

In this way, it is possible to provide the memory element in which the driving voltage is lowered even though the crystalline organic ferroelectric material is used to form the ferroelectric layer. Moreover, such memory element is highly reliable because an amount of leakage current is reduced and short circuit is prevented.

A memory device according to a fourth aspect of the invention includes the above-mentioned memory element.

In this way, it is possible to provide the memory device in which the driving voltage is lowered even though the crystalline organic ferroelectric material is used to form the ferroelectric layer. Moreover, such memory device is highly reliable because an amount of leakage current is reduced and short circuit is prevented.

An electronic apparatus according to a fifth aspect of the invention includes the above-mentioned memory device.

In this way, it is possible to provide an electronic apparatus in which the driving voltage is lowered even though the crystalline organic ferroelectric material is used to form the ferroelectric layer. Moreover, such electronic apparatus is highly reliable because an amount of leakage current is reduced and short circuit is prevented.

A method for manufacturing a transistor according to a sixth aspect of the invention includes forming a source region and a drain region with a predetermined space therebetween on a substrate, forming a semiconductor layer such that the semiconductor layer contacts with both the source region and the drain region, forming a gate insulating layer on a first face of the semiconductor layer, the first face being on an opposite side to the substrate side, and the gate insulating layer being mainly made of a crystalline organic ferroelectric material, and forming a gate electrode on a second face of the gate insulating layer, the second face being on an opposite side to the semiconductor layer side, the gate electrode being formed by ejecting an vaporized electrode material in a direction inclined with respect to a normal line direction of the substrate and depositing the vaporized electrode material on the second face of the gate insulating layer.

According to the sixth aspect of the invention, even though a rough face made by the crystal grains of the organic ferroelectric material is formed on the side of the gate insulating layer where the gate electrode is to be formed, it is possible to prevent or stop the electrode material from entering into the concave portions of the rough face when the gate electrode is formed. Moreover, it is possible to prevent gaps between the gate electrode and the semiconductor layer from becoming small in some place. Consequently, this prevents the increase of leakage current and a short circuit between the gate electrode and the semiconductor layer in the memory element even though the gate insulating layer is made thin. It follows that the gate insulating layer can be made thinner, which makes it possible to lower the driving voltage.

### BRIEF DESCRIPTION OF THE DRAWINGS

The invention will be described with reference to the accompanying drawings, wherein like numbers reference like elements.

FIG. 1 is a longitudinal sectional view of a memory element according to a first embodiment of the invention.

FIGS. 2A through 2E are drawings for showing a manufacturing method of the memory element shown in FIG. 1.

FIG. 3 is a schematic sectional view of film forming equipment which is used in the method for manufacturing the memory element shown in FIG. 1.

FIG. 4 is a drawing schematically showing a circuit configuration of an organic ferroelectric memory (a memory array) that includes a memory element 1 according to the invention.

FIG. 5 is a schematic sectional view of film forming equipment which is used in a method for manufacturing a memory element according to a second embodiment of the invention.

FIG. 6 is a schematic sectional view of film forming equipment which is used in a method for manufacturing a memory element according to a third embodiment of the invention.

FIGS. 7A and 7B are longitudinal sectional views of a memory element according to a fourth embodiment of the invention.

FIGS. 8A through 8E are drawings for showing a manufacturing method of the memory element shown in FIG. 7.

FIG. 9 is a drawing showing a schematic structure of a memory device equipped with the memory element shown in FIG. 7.

### DESCRIPTION OF EXEMPLARY EMBODIMENTS

Embodiments of a method for manufacturing a memory element, a memory element, a memory device, an electronic apparatus and a method for manufacturing a transistor according to the invention will be described.

### First Embodiment

A first embodiment of the invention is hereinafter described.

Memory Element

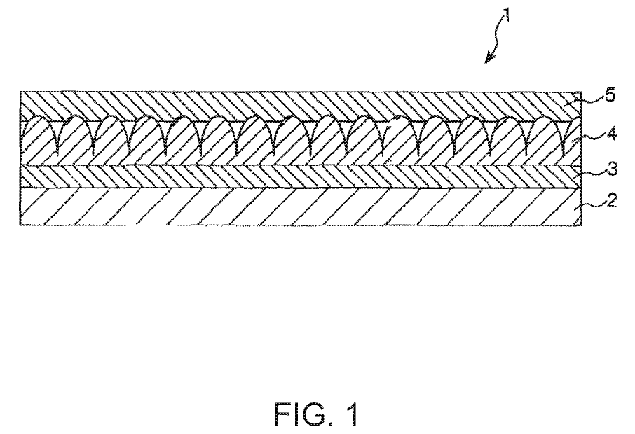

A memory element in other words a memory element formed by a method for manufacturing a memory element according to the first embodiment is described with reference to FIG. 1.

FIG. 1 is a longitudinal sectional view of a memory element according to the first embodiment. The upper side in FIG. 1 is hereinafter referred as the “upper side” and the lower side in FIG. 1 is referred as the “lower side” for convenience of explanation. The memory element 1 shown in FIG. 1 includes a substrate 2, on top of which there is a first electrode 3 (a lower electrode), on top of which there is a ferroelectric layer 4 (a recording layer), and on top of which there is a second electrode 5 (an upper electrode). In other words, in the memory element 1, a structure (or a capacitor) including the ferroelectric layer 4 between the first electrode 3 and the second electrode 5 is supported by the substrate 2 in the first electrode 3 side.

Data writing and data reading in/from such memory element 1 are performed by applying a voltage (an electric field) between the first electrode 3 and the second electrode 5. The polarized state in the ferroelectric layer 4 is retained even after the application of the electric field has stopped. Utilizing this property, the memory element 1 can be used as a nonvolatile memory (for instance a hereinafter described memory device 100).

The substrate 2 can be for example a glass substrate, a plastic substrate (a resin substrate) made of polyimide, polyethylene terephthalate (PET), polyethylene naphthalate (PEN), polymethyl methacrylate (PMMA), polycarbonate (PC), polyether sulfone (PES), aromatic polyester (liquid crystal polymer) and the like, a quartz substrate, a silicon substrate., a gallium arsenide substrate or the like. Where the memory element 1 is formed to have flexibility, a resin substrate is adopted as the substrate 2.

A base layer may be further provided on the substrate 2. The base layer is provided for example in order to prevent ions from being diffused from the surface of the substrate 2 and to enhance the adhesion (joint) of the first electrode 3 and the substrate 2.

Such base layer can be made of any material. However, it is preferable that the base layer be made of silicon oxide (SiO₂), silicon nitride (SiN), polyimide, polyamide, insoluble cross-linked polymers and the like.

A thickness of the substrate 2 is not particularly limited however it is preferable that it be 10-2,000 μm.

The first electrode 3 is formed on the upper face of the substrate 2 (on one face of the substrate 2). The first electrode 3 can be made of any material provided it is conductive. For example, the first electrode 3 can be made of conductive materials such as Pd, Pt, Au, W, Ta, Mo, Al, Cr, Ti, Cu and alloys thereof; conductive oxides such as indium tin oxide (ITO), fluorine-doped tin oxide (FTO), antimony-doped tin oxide (ATO) and SnO₂; carbon-based materials such as carbon black, carbon nanotube and fullerene; conductive polymers such as polyacetylene, polypyrrole, polythiophene including poly-ethylenedioxythiophene (PEDOT), polyaniline, poly(p-phenylene), polyfluorene, polycarbazole, polysilane and derivatives thereof. One of the above-mentioned conductive materials or any combination thereof can be used for the first electrode 3. The above-mentioned conductive polymers are usually doped with polymers of iron oxide, iodine, inorganic acid, organic acid, polystyrene sulfonic acid or the like and conductivity is imparted to the polymers. It is preferable that the first electrode 3 be made of Al, Au, Cr, Ni, Cu, Pt or alloys thereof. In this case, the first electrode 3 can be easily and cost-efficiently formed by using an electroless plating method and besides the property of the memory element 1 can be improved.

A thickness of the first electrode 3 is not particularly limited. However, about 10-1,000 nm is preferable and about 50-500 nm is more preferable.

The ferroelectric layer 4 is formed on the upper face of the first electrode 3 (the side of the first electrode 3 which is the opposite side to the substrate 2 side). The ferroelectric layer 4 is mainly made of a crystalline organic ferroelectric material.

The ferroelectric layer 4 is mainly made of the organic ferroelectric material that has a polarization axis extending in the direction orthogonal to the face of the substrate 2. Thereby, polarization inversion occurs in the ferroelectric layer 4 when an electric field is applied in the thickness direction of the ferroelectric layer 4. The ferroelectric layer 4 is made of the crystalline organic ferroelectric material and particularly formed by a hereinafter described manufacturing method so that it has a rough surface of crystal grains on the second electrode 5 side, which is schematically shown in FIG. 1.

The organic ferroelectric material includes for example a copolymer of vinylidene fluoride and trifluoroethylene (P[VDF/TrFE]), a polymer of vinylidene fluoride (PVDF) and the like.

A thickness (average thickness) of the ferroelectric layer 4 is not particularly limited however about 5-500 nm is preferable and about 10-200 nm is more preferable. In this way various driving properties of the memory element 1 (and the organic ferroelectric memory and the electronic apparatus equipped with the memory element 1) can be improved.

Provided on the upper face of such ferroelectric layer 4 (the face of the ferroelectric layer 4 which is opposite face to the first electrode 3) is the second electrode 5.

The second electrode 5 is formed by a hereinafter described manufacturing method in such a way that it will not enter the concave portions in the above-mentioned rough face of the ferroelectric layer 4 made by the crystal grains. In other words, air gaps are formed in the concave portions of the crystal grain rough face of the ferroelectric layer 4 and provided between the second electrode 5 and the ferroelectric layer 4. Therefore, even where pinholes or defects made by the crystal grains are formed in the ferroelectric layer 4 when the ferroelectric layer 4 is made thin, the air gaps can prevent short-circuit between the first electrode 3 and the second electrode 5 from occurring. In addition, the distances between the first electrode 3 and the second electrode 5 can be made constant throughout the face.

The second electrode 5 can be made of the same material as that of the first electrode 3. A thickness of the second electrode 5 is not particularly limited however about 10-1,000 nm is preferable and about 50-500 nm is more preferable.

Method for Manufacturing Memory Element

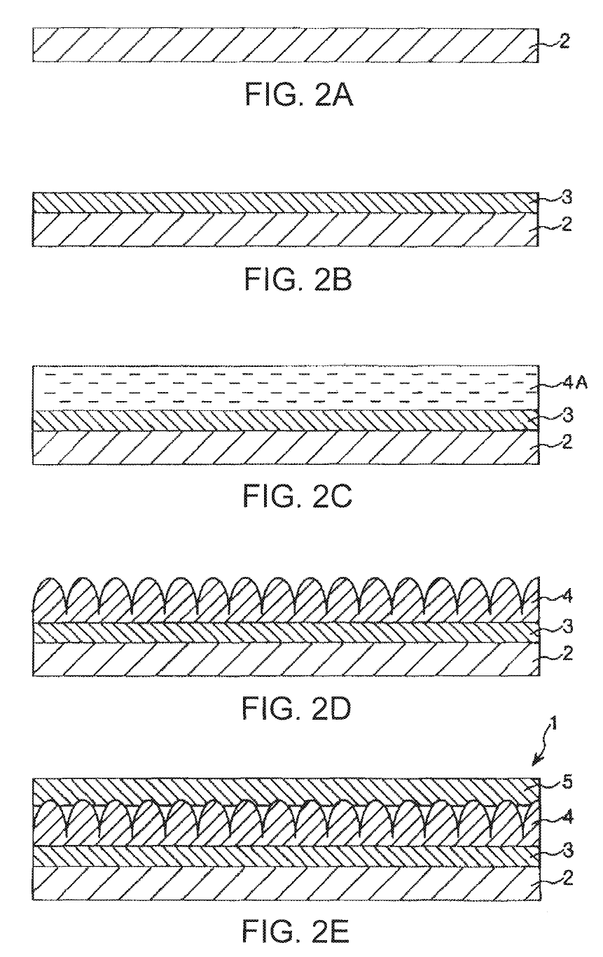

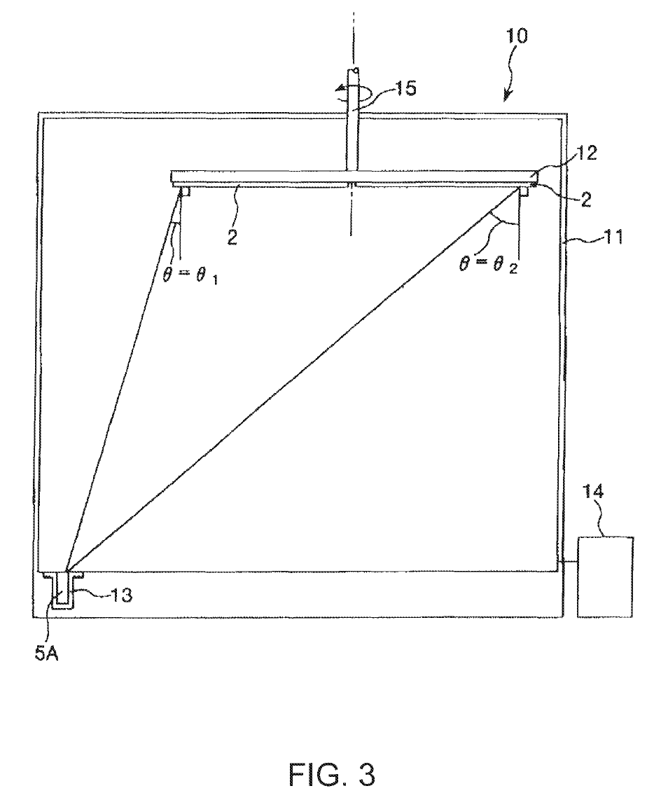

Next, a method for manufacturing a memory element according to the invention is described. A manufacturing method of the memory element 1 is described below by way of example of the invention with reference to FIG. 2 and FIG. 3.

FIGS. 2A through 2E are drawings for showing the manufacturing method of the memory element shown in FIG. 1. FIG. 3 is a schematic sectional view of film forming equipment which is used in the method for manufacturing the memory element shown in FIG. 1.

The method for manufacturing the memory element 1 includes: (1) a process of forming the first electrode 3, (2) a process of forming the ferroelectric layer 4 and (3) a process of forming the second electrode 5.

Each process is hereinafter described in detail in the above-mentioned order.

(1) Process of Forming the First Electrode 3

Referring to FIG. 2A, the substrate 2 that is for example a semiconductor substrate, a glass substrate, a resin substrate or the like is firstly provided. The first electrode 3 is formed on the upper face of the substrate 2 as shown in FIG. 2B.

In case where a resin substrate is used as the substrate 2, the obtained memory element 1 or the memory device 100 (an organic ferroelectric memory) can be made flexible.

The fabrication method of the first electrode 3 is not particularly limited. The first electrode 3 can be formed by for example physical vapor deposition (PVD) methods such as a vacuum deposition method, a sputtering method (low temperature sputtering) and ion-plating; chemical vapor deposition (CVD) methods such as a plasma CVD, a heat CVD and a laser CVD; wet plating methods such as an electrolytic plating, a dip plating and an electroless plating; solution applying methods such as a spin-coating method and a liquid source misted chemical deposition (LSMCD) method; various printing methods such as a screen printing method and an inkjet method or the like.

(2) Process of Forming the Ferroelectric Layer 4

A liquid material containing the organic ferroelectric material is subsequently applied on the face of the first electrode 3 which is the opposite one to the one facing the substrate 2. The liquid material is then dried and crystallized, forming the ferroelectric layer 4.

More specifically, referring to FIG. 2C, a liquid material 4A containing the crystalline organic ferroelectric material is applied on the face of the fist electrode 3 which is opposite to the substrate 2 (so as to form a film of the liquid material 4A).

The liquid material 4A is a solution in which the crystalline organic ferroelectric material is solved in a solvent or dispersed in a dispersion medium.

It is preferable that the liquid material 4A be a solution in which the crystalline organic ferroelectric material is solved in a solvent. In this way, the liquid material 4A can be easily provided (applied) to the substrate 2 and it is relatively easy to form a film having a low crystallinity and a uniform thickness.

The above-mentioned material used to form the ferroelectric layer 4 can also be used for the organic ferroelectric material of the liquid material 4A. Particularly, the copolymer of vinylidene fluoride and trifluoroethylene or a polymer of vinylidene fluoride, or a combination thereof is preferable for the organic ferroelectric material. More particularly, the copolymer of vinylidene fluoride and trifluoroethylene (or P[VDF/TrFE]) is preferred as the organic ferroelectric material for the reason that the ferroelectricity which is essential for the memory element 1 can be easily obtained.

The liquid material 4A may contain other materials in addition to the organic ferroelectric material and a solvent or a dispersion medium.

As the solvent or the dispersion medium for the liquid material 4A, any material can be used provided it can dissolve or disperse the organic ferroelectric material. For example, there are inorganic solvents such as nitric acid, sulfuric acid, ammonia, hydrogen peroxide, water, carbon disulfide, carbon tetrachloride and ethylene carbonate; ketone series solvents such as methyl-ethyl-ketone (MEK), acetone, diethylketone, methyl isobutyl ketone (MIBK), methyl isopropyl ketone (MIPrK), methyl isopentyl ketone (MIPeK), acetylacetone and cyclohexane; alcohol series solvents such as diethylene carbonate (DEC), methanol, ethanol, isopropanol, ethylene glycol, diethylene glycol (DEG) and glycerine; ether series solvents such as diethylether, diisopropylether, 1,2-dimethoxyethane (DME), 1,4-dioxan, tetrahydrofuran (THF), tetrahydropyran (THP), anisole, diethylene-glycol-dimethyl ether (diglyme) and diethylen-glycol-ethyl ether (carbitol); cellosolve series solvents such as methyl cellosolve, ethyl cellosolve and phenyl cellosolve. Furthermore, there are aliphatic hydrocarbon series solvents such as hexane, pentane, heptane and cyclohexane; aromatic hydrocarbon series solvents such as toluene, xylene and benzene, heteroaromatic compound series solvents such as pyridine, pyrazine, furan, pyrrole, thiophene and methyl pyrrolidone; amid series solvents such as N,N-dimethyl formamide (DMF) and N,N-dimethyl acetamide (DMA); halogen compound series solvents such as dichloromethane, chloroform and 1,2-dichloroethane; ester series solvents such as acetic ether, methyl acetate and formic ether; sulfur compound series solvents such as dimethyl sulfoxide (DMSO) and sulfolane; nitrile series solvents such as acetonitrile, propionitrile and acrylonitrile; and organic acid solvents such as formic acid, acetic acid, trichloroacetic acid and trifluoroacetic acid and other various organic solvents. Mixed solvents containing the above-mentioned materials can also be used.

Where the P(VDF/TrFE) is adopted as the organic ferroelectric material, organic solvents such as MEK (or methyl-ethyl-ketone: 2-butanone), MIPrK (or methyl isopropyl ketone: 3-methyl-2-butanone), 2-pentanone, MIBK (or methyl isobutyl ketone: 4-methyl-2-pentanone), 2-hexanone, 2,4-dimethyl-3-pentanone, 4-heptanone, MIPeK (or methyl isopentyl ketone: 5-methyl-2-hexanone, 2-heptanone, 3-heptanone, cyclohexane and DEC (or diethylene carbonate) or any mixed solvents thereof are preferably used as the solvent.

It is preferable that the content of the organic ferroelectric material in the liquid material 4A be 0.1-8.0 wt %, more preferably 0.2-4.0 wt %. In this way, the liquid material 4A can be easily applied to the substrate 2 and it is relatively easy to form a film having a low crystallinity and a uniform thickness.

A method to provide the liquid material 4A (an application method) is not particularly limited. For example, a spin-coating method, a liquid source misted chemical deposition (LSMCD) method, an inkjet method or the like can be adequately adopted.

In this case, a surface preparation such as a hydrophilicity imparting treatment and a hydrophobicity imparting process which will be selected according to the type of the solvent of the liquid material can be performed in advance to the place where the liquid material is to be applied. This allows the liquid material to be selectively deposited and patterned. In this way, it is not necessary to separately perform a patterning process.

The liquid material 4A in the film form made in the above-described way is then dried (by removing the solvent) and a low-crystalline film (an amorphous film) which is an intermediate product film of the ferroelectric layer 4 is formed.

The low-crystalline film is a film which is mainly composed of the organic ferroelectric material and has lower crystallinity than that of the finished organic ferroelectric material of the ferroelectric layer 4. A degree of the crystallinity of such organic ferroelectric material of the low-crystalline film is preferably 0.001-80%, more preferably 50% or less when the crystallinity of the organic ferroelectric material of the finished ferroelectric layer 4 is presumed to be 100%.

Methods for drying the liquid material 4A or methods for removing the solvent or the dispersion liquid from the liquid material 4A are not particularly limited. For example, there are external heat drying methods with a hotplate, an oven or the like, internal heat drying methods with micro-wave or the like, hot-air feeding methods, radiant heat transfer drying methods with infrared rays or the like, vacuum decompression methods and the like.

In the case that the solvent or the dispersion liquid of the liquid material 4A is highly volatile and the applied film hardly includes the residual solvent or the residual dispersion liquid, the above-mentioned drying process is not needed to be performed.

When a heat process is used to dry the liquid material 4A, the process is performed at a temperature lower than the appropriate crystallization temperature of the organic ferroelectric material. Such temperature depends on the type of the organic ferroelectric material, the solvent and the film thickness of the liquid material 4A. More specifically, such temperature is preferably from the room temperature to 140° C. inclusive, more preferably from the room temperature to 100° C. inclusive. In this case, a treating time of the heat process also depends on the type of the organic ferroelectric material and the film thickness of the liquid material 4A. More specifically, such treating time is preferably for 0.5-120 minutes, more preferably for 1-30 minutes.

When the low-crystalline film is formed by applying and drying the liquid material 4A, the application process can be repeated more than one time and the above mentioned application process and the above mentioned drying process can be alternatively repeated.

Referring now to FIG. 2D, the above-described low-crystalline film is then crystallized so as to form the ferroelectric layer 4.

Methods for the crystallization are not particularly limited. As such crystallization method includes for example methods using a hotplate, an oven, a vacuum oven or the like, methods utilizing internal heating with a microwave or the like and methods utilizing radiation heat with an infrared ray or the like. The crystallization heating process using a hotplate, an oven, a vacuum oven or the like is preferably adopted.

If a heat process of the crystallization is performed at an appropriate temperature to crystallize the low-crystalline film, it is possible to efficiently crystallize the organic ferroelectric material in the low-crystalline film for a relatively short time period while preventing undesired structural change of the crystal in the organic ferroelectric material.

Where the heat process is used for the crystallization, the treatment temperature should be at the crystallization temperature of the organic ferroelectric material or higher and at the melting point or lower. The treatment temperature depends on the type of the organic ferroelectric material. In case of P(VDF/TrFE) (VDF/TrFE=75/25), the treatment temperature is preferably 130-150° C., more preferably 35-145° C.

The treating time period of the crystallization process depends on the type of the organic ferroelectric material and the film thickness of the liquid material 4A. However, the treating time period of the crystallization process is preferably 0.5-120 minutes, more preferably for 1-30 minutes.

The crystallization can be performed in the air. However, it is preferable that it is performed in inert atmospheres such as nitrogen and argon or in vacuum.

The above-described manufacturing method of the ferroelectric layer 4 includes the process in which the low-crystalline film is formed by applying and drying the liquid material 4A and the process in which the ferroelectric layer 4 is formed by increasing the degree of the crystallinity of the low-crystalline film. Therefore, the organic ferroelectric material can be in a fluid form during the period from the application of the liquid material 4A to the crystallization. This makes it relatively easy to control the degree of the crystallinity of the ferroelectric layer 4 and to have a desired crystallinity.

(3) Process of Forming the Second Electrode 5

Referring now to FIG. 2E, the second electrode 5 is formed on the ferroelectric layer 4. A vapor deposition method is applied to form the second electrode 5. More specifically, vaporized electrode material 5A (constituent material or precursor of the second electrode 5) is ejected in a direction having a certain angle from the normal line of the substrate 2, and the vaporized material is deposited on the ferroelectric layer 4. In this way, the second electrode 5 is formed.

As such vapor deposition method, there are physical vapor deposition (PVD) methods including vacuum deposition, sputtering and the like and chemical vapor deposition (CVD) methods. In this embodiment, an example where the second electrode 5 is formed by a vacuum deposition method using film forming equipment 10 shown in FIG. 3 is described.

The film forming equipment 10 shown in FIG. 3, which is a vacuum deposition apparatus, has a chamber 11 (vacuum chamber), a substrate holder 12 holding the substrate 2 (on which the first electrode 3 and the ferroelectric layer 4 have formed) and provided in the chamber 11, and a material supplying source 13 (a crucible) provided in the chamber 11. The material supplying source 13 vaporizes the electrode material 5A (a film forming material) and supplies it to the substrate 2.

The chamber 11 further has an air displacement pump 14 (a decompression measure) that pumps out the air inside and controls the pressure.

The substrate holder 12 is installed on a ceiling of the chamber 11. The substrate holder 12 is secured to a rotation shaft 15 and the substrate holder 12 is rotatable (moveable) centering around the rotation shaft 15. In other words, the substrate holder 12 rotates or moves around on the axis that extends in the thickness direction of the substrate 2 which is held by the substrate holder 12. With such structure, it is possible to prevent unevenness in the electrode material 5A deposition depending on a position on the substrate 2 and to obtain the second electrode 5 with a uniform thickness and a uniform film quality.

The substrate holder 12 holds more than one substrate 2 so that more than one substrate 2 can be simultaneously treated and the second electrode 5 can be obtained on each substrate 2.

In this case, it is preferable that the substrate holder 12 hold a plurality of the substrates 2 in the same plane which is orthogonal to the rotation center of the substrate holder 12 and each of the substrates 2 is placed at the approximately same distance from the rotation center. In this way, it is possible to prevent unevenness in the electrode material 5A deposition among the substrates 2 and to make each second electrode 5 formed on each substrate 2 have the same quality.

The material supplying source 13 (the crucible) that discharges the vaporized electrode material 5A is placed at a position where is not directly below the substrate holder 12 on the bottom of the chamber 11. In other words, the substrate holder 12 holds the substrate 2 such that the substrate 2 inclines with respect to the material supplying source 13. In this way, the vaporized electrode material 5A can be ejected in the inclined direction with respect to the normal line direction of the substrate 2 with such relatively simple structure.

The material supplying source 13 stores the electrode material 5A (the above-mentioned material for forming the second electrode 5) and heats and vaporizes (evaporates or sublimates) the electrode material 5 by an unshown heating measure. Any heating measure such as a resistance heating and an electron beam heating can be used here.

The ferroelectric layer 4 has the rough face made by the crystal grains of the organic ferroelectric material on the side where the second electrode 5 is to be formed as described above. It is preferable that the direction in which the vaporized electrode material 5A is ejected be inclined with respect to the normal direction of the substrate 2 so that it can stop or prevent the electrode material 5A from entering into the concave portions of the rough face. In this way, it is possible to more assuredly prevent the gaps between the first electrode 3 and the second electrode 5 from becoming small in some place.

More specifically, an preferable angle “θ” (see FIG. 3, hereinafter also referred as “a deposition angle θ”) between the ejecting direction of the vaporized electrode material 5A and the normal line of the substrate 2 around the ferroelectric layer 4 is 20-70°, more preferably 30-60°.

In this way, it is possible more assuredly to prevent the electrode material 5A from entering into the concave portions of the rough face when the second electrode 5 is formed, even though the rough face made by the crystal grains of the organic ferroelectric material on the side of the ferroelectric layer 4 where the second electrode 5 is to be formed.

If the angle θ is smaller than the above-mentioned preferred range, the electrode material 5A could get deep into the concave portions of the rough face depending on the geometry of the rough face of the ferroelectric layer 4. If the angle θ is larger than the above-mentioned preferred range, a deposition speed drops dramatically and unevenness in the deposition tends to occur around the upper position of the substrate 2 and the substrate holder 12 depending on the conditions such as a rotation speed of the substrate holder 12.

Though the value of the angle θ differs depending on the position on the substrate 2 and the substrate holder 12 such that an angle “θ1” and an angle “θ2” shown in FIG. 3, it is preferable that the angle satisfy the value in the above-mentioned range wherever the angle is measured on the substrate 2 or the substrate holder 12. In other words, where the film forming equipment 10 is used, both the angle θ1 that is the minimum value of the angle θ and the angle θ2 that is the maximum value of the angle θ satisfy the above mentioned preferable range. In this way, the above described advantageous effect can be securely obtained.

Processes of forming the second electrode 5 by using such film forming equipment 10 are now described. The substrate 2 is firstly set in the substrate holder 12. At this point, the first electrode 3 and the ferroelectric layer 4 will have been already formed on the substrate 2 through the above described processes though these are not shown in FIG. 3. The substrate 2 is set in the substrate holder 12 in such a way that the first electrode 3 and the ferroelectric layer 4 side of the substrate 2 faces the material supplying source 13 side. A mask for film formation is provided between the ferroelectric layer 4 and the material supplying source 13 if required.

The chamber 11 is then decompressed by driving the air displacement pump 14. The degree of the decompression (degree of vacuum) is not particularly limited. However, about 1×10⁻⁵-1×10⁻² Pa is preferable, and more preferably about 1×10⁻⁴-1×10⁻³ Pa.

The substrate 2 is then moved by rotating the rotation shaft 15. In this way, it is possible to reduce the difference in the deposition angles that depend on the positional relations between the material supplying source 13 and parts such as the substrate 2 and the substrate holder 2.

It is preferable that a rotation frequency of the rotation shaft 15 be about 1-50 rpm, more preferably 10-20 rpm. With such rotation, the second electrode 5 can be formed more uniformly.

The electrode material 5A in the material supplying source 13 is subsequently heated while the substrate 2 is rotating as described above, and the electrode material 5A is vaporized (evaporated or sublimated).

The vaporized electrode material 5A is deposited (reached) on the substrate 2 (more specifically on the ferroelectric layer 4), forming the second electrode 5.

The memory element 1 can be manufactured in the above described way.

According to the above described method, the vaporized electrode material 5A is ejected in an inclined direction with respect to the normal direction of the substrate 2 and deposited on the ferroelectric layer 4 so as to form the second electrode 5. Thereby, it is possible to prevent or stop the electrode material 5A from entering into the concave portions of the rough face even though the rough face made by the crystal grains of the organic ferroelectric material on the side of the ferroelectric layer 4 where the second electrode 5 is to be formed. Moreover, it is possible to prevent the gaps between the first electrode 3 and the second electrode 5 from becoming small in some place. Consequently, this prevents the increase of the leakage current and a short circuit between the first electrode 3 and the second electrode 5. It follows that the ferroelectric layer 4 can be made thinner which makes it possible to lower the driving voltage.

In the above-described way, the memory element 1 of which the driving voltage can be lowered can be obtained even though the crystalline organic ferroelectric material is used to form the ferroelectric layer 4. Such memory element 1 is highly reliable because the leakage current is reduced and the short circuit is prevented.

Such memory element 1 can be applied to organic ferroelectric memories (memory arrays) of a single transistor and a single capacitor type (or 1T1C type), a two transistor and two capacitor type (or 2T2C type) and a cross-point type (or CP type). More specifically, a capacitor part of the above described memory element 1 can be used as a capacitor part of the 1T1C type, 2T2C type or CP type memory array.

Memory Device

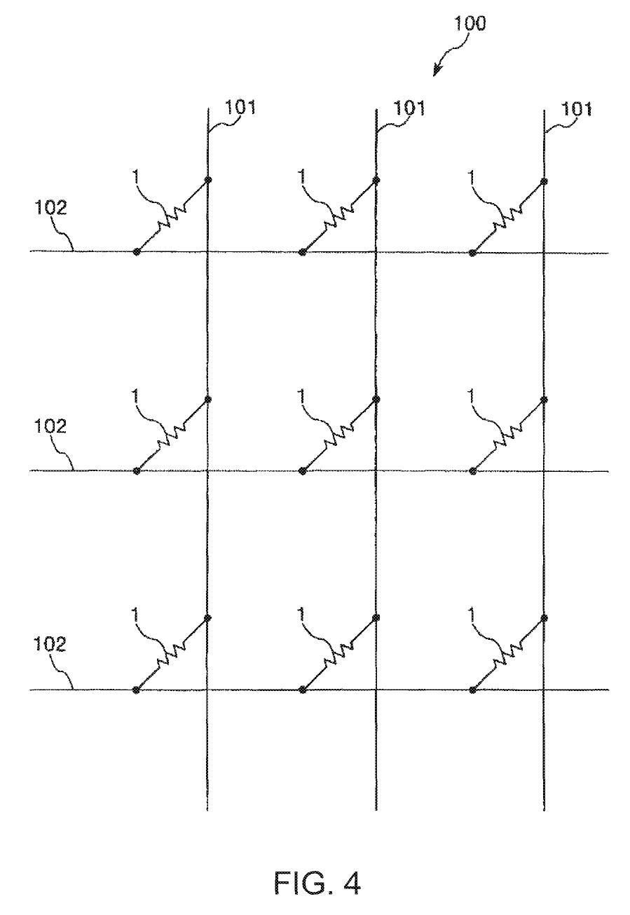

Next, as an example of the memory device according to the invention, a CP-type organic ferroelectric memory equipped with the memory element 1 is described with reference to FIG. 4.

FIG. 4 is a drawing schematically showing a circuit configuration of an organic ferroelectric memory (a memory array) that includes the memory element 1 according to the embodiment of the invention.

Referring FIG. 4, the memory device 100 is an organic ferroelectric memory having a memory array made of a plurality of CP type memory cells.

More specifically, the memory device 100 has the memory array in which a first signal electrode 101 for selecting a row and a second signal electrode 102 for selecting a column are arranged so as to orthogonally cross each other. One of the first signal electrode 101 or the second signal electrode 102 is a word line, and the other is a bit line. The memory element 1 according to the embodiment is provided at each intersection of these lines. The memory element 1 is schematically denoted as a resistance coupled around an intersection in FIG. 4.

With such memory device 100, it is possible to lower the driving voltage even though the crystalline organic ferroelectric material is used to form the ferroelectric layer 4. Moreover, such memory device 100 is highly reliable because an amount of leakage current is reduced and short circuit is prevented.

### Second Embodiment

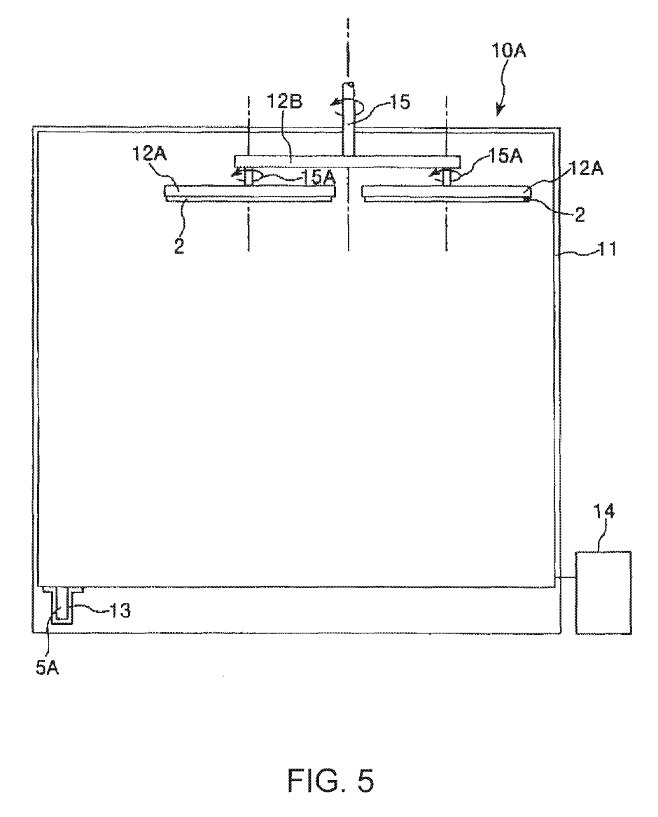

A second embodiment of the invention is now described with reference to FIG. 5.

FIG. 5 is a schematic sectional view of film forming equipment which is used in a method for manufacturing a memory element according to the second embodiment.

In the following description, structures or elements of the second embodiment which are different from those of the first embodiment described above will be mainly described and explanations for the same elements and configurations as those of the first embodiment will be omitted.

The second embodiment is almost same as the first embodiment other than the film forming equipment used to form the ferroelectric layer 4.

More specifically, film forming equipment 10A according to the second embodiment has a substrate holder 12A that holds the substrate 2. The substrate holder 12A is supported through the rotation shaft 15 that can rotate around the axis extending in the thickness direction of the substrate 2 and by a rotation member 12B which is rotatable or moveable centering on the rotation shaft 15. With such structure, the plurality of the substrates 2 can rotate around on the rotation shaft 15 and each substrate 2 can rotate around on the substrate holder 12A.

In other words, the substrate holder 12A rotates or moves each substrate 2 around on the axis which extends from approximately the center of the substrate 2 in the thickness direction of the substrate 2. In this way, it is possible to prevent the unevenness in the electrode material 5A deposition among the substrates 2 and the unevenness in the electrode material 5A deposition depending on a position on the substrate 2.

### Third Embodiment

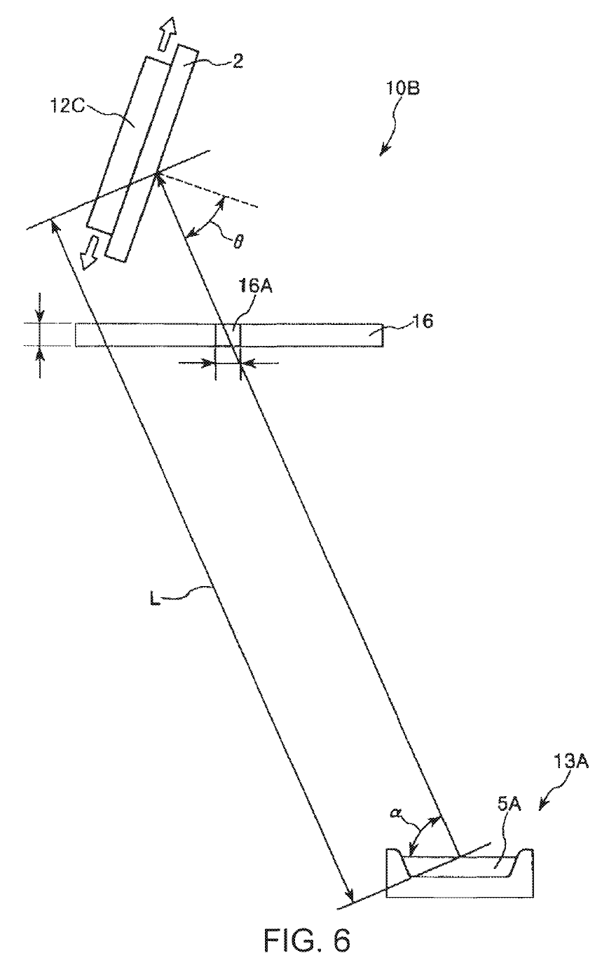

A third embodiment of the invention is now described with reference to FIG. 6.

FIG. 6 is a schematic sectional view of film forming equipment which is used in a method for manufacturing a memory element according to the third embodiment.

In the following description, structures or elements of the third embodiment which are different from those of the first embodiment described above will be mainly described and explanations for the same elements and configurations as those of the first embodiment will be omitted.

The third embodiment is almost same as the first embodiment other than a structure of the film forming equipment used to form the ferroelectric layer 4.

Referring to FIG. 6, a material supplying source 13A containing the electrode material 5A and a substrate holder 12C for holding the substrate 2 are provided in a chamber (unshown) in third embodiment. A slit plate 16 that has a slit-shaped opening 16A is further provided between the material supplying source 13A and the substrate holder 12C.

In other words, the slit plate 16 having the slit-shaped opening 16A is provided between the material supplying source 13A and the substrate 2 in the process of forming the second electrode 5.

The substrate holder 12C translates the substrate 2 in the direction orthogonal to the longer direction of the opening 16A of the slit plate 16 while it maintains a deposition angle θ (the angle θ shown in FIG. 6). In such film forming equipment 10B, the electrode material 5A is subsequently heated by a heating measure (unshown) provided in the material supplying source 13A and the electrode material 5A is vaporized (evaporated) while the substrate 2 is translated by the substrate holder 12C as described above. The vaporized electrode material 5A reaches the face of the substrate 2 (more specifically the face of the ferroelectric layer 4 opposite to the first electrode 3) through the opening 16A of the slit plate 16.

In other words, the substrate 2 is moved in the shorter direction of the opening 16A of the slit plate 16 and the vaporized electrode material 5A which went through the opening 16A of the slit plate 16 is deposited on the substrate 2 at the same time. In this way, it is possible to prevent unevenness in the electrode material 5A deposition depending on a position on the substrate 2 and to obtain the second electrode 5 with a uniform thickness and a uniform film quality.

### Fourth Embodiment

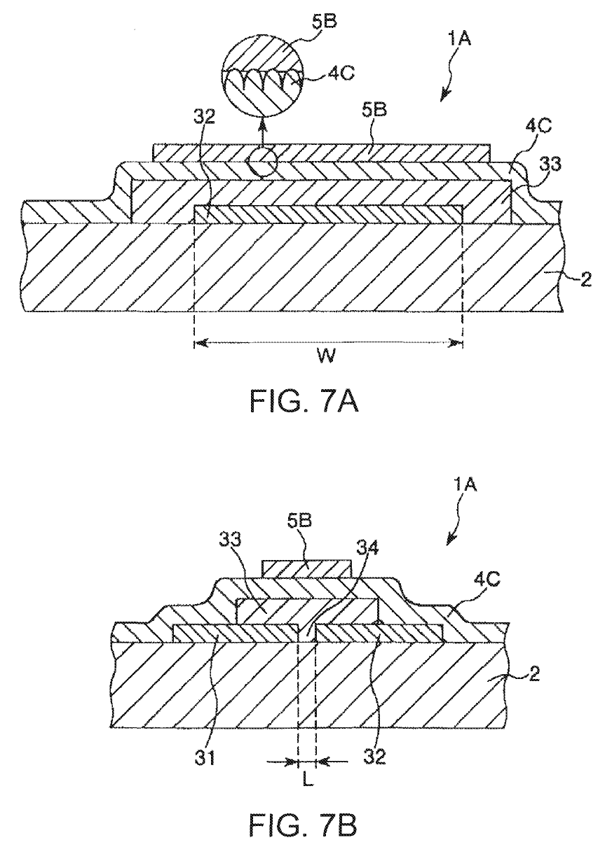

A forth embodiment of the invention is now described with reference to FIGS. 7-9.

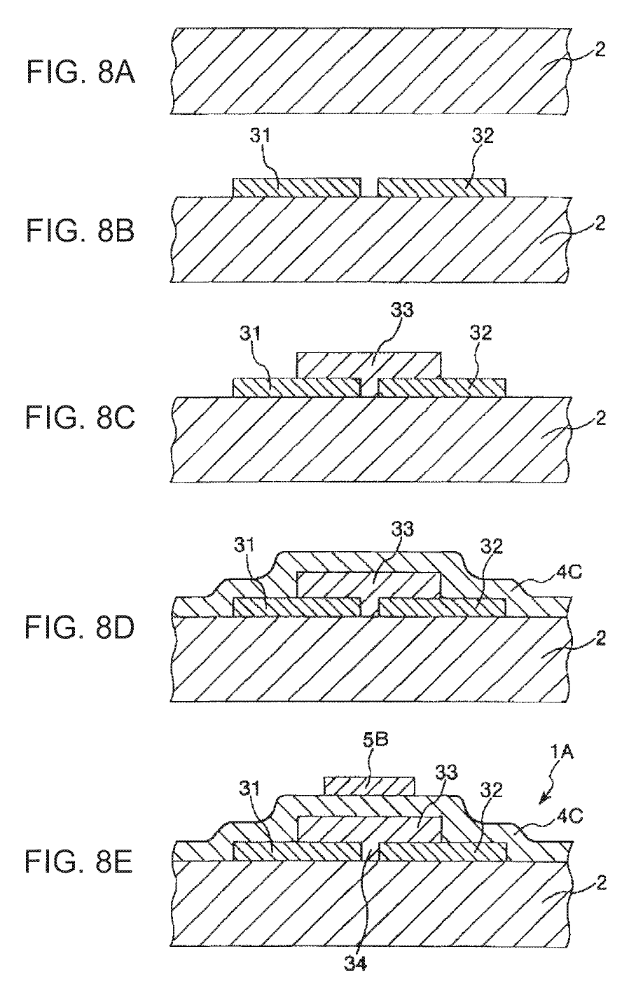

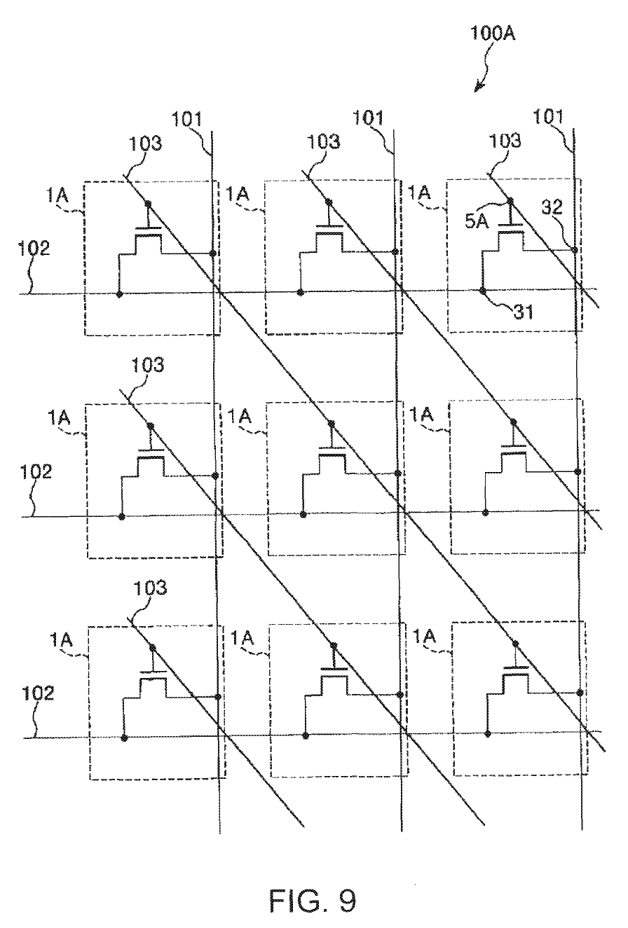

FIGS. 7A and 7B are longitudinal sectional views of a memory element according to the fourth embodiment. FIGS. 8A through 8E are drawings for showing a manufacturing method of the memory element shown in FIG. 7. FIG. 9 is a drawing showing a schematic structure of a memory device equipped with the memory element shown in FIG. 7. The upper sides in FIG. 7 and FIG. 8 are hereinafter referred as the “upper side” and the lower side in FIG. 7 and FIG. 8 are referred as the “lower side” for convenience of explanation.

In the following description, structures or elements of the fourth embodiment which are different from those of the first embodiment described above will be mainly described and explanations for the same elements and configurations as those of the first embodiment will be omitted.

Referring now to FIG. 7, a memory element 1A is an organic ferroelectric memory of the single transistor type (or 1T type).

The memory element 1A includes a source region 31 and a drain region 32 provided on the substrate 2 with a certain gap therebetween, a semiconductor layer 33 which contacts with both the source region 31 and the drain region 32 and is provided therebetween, a ferroelectric layer 4C (a recording layer) which is formed so as to cover the semiconductor layer 33, and a gate electrode 5B which is the second electrode formed on the ferroelectric layer 4C.

Data can be recorded (or written) in the memory element 1A by applying a voltage between the gate electrode 5B and the source region 31 and the drain region 32, and changing the polarized state in the ferroelectric layer 4C. The polarized state is retained even after the application of the electric field has stopped. The record can be reproduced (read out) by detecting the electric current which flows between the source region 31 and the drain region 32. Utilizing this property, the memory element 1A can be used as a nonvolatile memory.

Referring now to FIG. 7B, a part of the semiconductor layer 33 where is between the source region 31 and the drain region 32 is a channel region 34 though which carriers are transferred in the memory element 1A. In this channel region 34, the length in which the carries are transferred or a distance between the source region 31 and the drain region 32 is a channel length L, and the length orthogonal to the channel length L is a channel width W.

Such memory element 1A has a top-gate structure in which the source region 31 and the drain region 32 are provided close to the substrate 2 side rather than the gate electrode 5B side with the ferroelectric layer 4 interposed therebetween.

Method for Manufacturing Memory Element

Next, a method for manufacturing the above described memory element 1A is described with reference to FIG. 8 as an example of the manufacturing method of the memory element according to the invention. The manufacturing method of the memory element 1A is same as that of the memory element 1 according to the above-described first embodiment concerning the formation of the gate electrode 5B.

The method of manufacturing the memory element 1A includes (1) a process of forming the source region 31, the drain region 32 and the semiconductor layer 33, (2) a process of forming the ferroelectric layer 4C by applying a liquid material containing the organic ferroelectric material and then drying and crystallizing it, and (3) a process of forming the gate electrode 5B on the ferroelectric layer 4C.

(1) Process of Forming the Source Region 31, the Drain Region 32 and the Semiconductor Layer 33

Referring to FIG. 8A, the substrate 2 which can be for example a semiconductor substrate, a glass substrate, a resin substrate or the like is firstly provided. The source region 31 and the drain region 32 are formed on the upper face of the substrate 2 as shown in FIG. 8B. The semiconductor layer 33 is subsequently formed a shown in FIG. 8C.

The fabrication methods of the source region 31, the drain region 32 and the semiconductor layer 33 are not particularly limited. The same method as that of the first electrode 3 as described above can be used.

Materials for forming the semiconductor layer 33 are not particularly limited. Various organic semiconductor materials and inorganic semiconductor materials can be used. The organic semiconductor materials are preferred in order to make the layer flexible.

The organic semiconductor materials include for example low-molecular organic semiconductor materials such as naphthalene, anthracene, tetracene, pentacene, hexacene, phthalocyanine, perylene, hydrazone, triphenylmethane, diphenylmethane, stilbene, arylvinyl, pyrazoline, triphenylamine, triarylainine, and oligothiophene or derivatives thereof and macromolecule organic semiconductor materials (conjugated polymer materials) such as poly-N-vinylcarbazole, polyvinyl pyrene, polyvinyl anthracene, polythiophene, polyalkylthiophene, polyhexylthiophene, poly(p-phenylene vinylene), polythienylene vinylene, polyarlylamine, pyrene formaldehyde resin; ethylcarbazole formaldehyde resin, fuluorene-bithiophene copolymer, fuluorene-allylamine copolymer, or derivatives thereof. One of the above-mentioned mateiral or more than one material combined can be adopted. It is preferable that the macromolecule organic semiconductor materials (the conjugated polymer materials) be mainly used. The conjugated polymer materials have a high mobility capability of carriers because of its characteristic distribution of the electron cloud.

It is preferable that a material mainly containing at least one of fuluorene-bithiophene copolymer, fuluorene-arlylamine copolymer and polyarlylamine or derivatives thereof be used as the polymer organic semiconductor material (the conjugated polymer material) since such material is not easily oxidized in the air and stable.

When the semiconductor layer 33 is mainly formed of such polymer organic semiconductor material, it is possible to trim the thickness and the weight of the memory element and to impart a fine flexibility to the memory element (the organic ferroelectric memory). Such memory element is appropriate for a nonvolatile memory mounted on various flexible electronics devices such as a flexible display.

It is preferable that a thickness of the semiconductor layer 33 (the organic semiconductor material) be about 1-500 nm, more preferably about 10-200 nm.

(2) Process of Forming the Ferroelectric Layer 4C

A liquid material containing the crystalline organic ferroelectric material is then applied (a film of the liquid material is formed) so as to cover the semiconductor layer 33. The liquid material is subsequently dried so as to form a low-crystalline film (an amorphous film) which is an intermediate product film for forming the recording layer 4C. This low-crystalline film can be formed in the same manner as the above described low-crystalline film of the first embodiment.

Referring to FIG. 8D, the low-crystalline film is further crystallized and the recording layer 4C is formed. The formation of the recording layer 4C can be performed in the same manner as the above described recording layer 4C.

(3) Process of Forming the Gate Electrode

Referring now to FIG. 8E, the gate electrode 5B is formed on the recording layer 4C.

This gate electrode 5B can be formed in the same manner as the above described process (1). Accordingly, the same advantageous effects as those of the first embodiment described above can be obtained.

More specifically, the vaporized electrode material 5A is ejected in an inclined direction with respect to the normal direction of the substrate 2 and deposited on the ferroelectric layer 4C so as to form the gate electrode 5B. Thereby, it is possible to prevent or stop the electrode material 5A from entering into the concave portions of the rough face even though the rough face made by the crystal grains of the organic ferroelectric material is formed on the side of the ferroelectric layer 4C where the gate electrode 5B is to be formed. Moreover, it is possible to prevent the gaps between the gate electrode 5B and the semiconductor layer 33 from becoming small in some place. Consequently, this prevents the increase of the leakage current and a short circuit between the gate electrode 5B and the semiconductor layer 33 in the memory element 1A even though the ferroelectric layer 4C is made thin. It follows that the ferroelectric layer 4 can be made thinner, which makes it possible to lower the driving voltage.

The memory element 1A can be manufacture in the above-described way. The memory element 1A manufactured by the above-mentioned method has a fine response and a fine hysteresis characteristic.

Memory Device

As another example of the memory device according to the invention, an organic ferroelectric memory using the memory element according to the embodiment is now described with reference to FIG. 9.

Referring FIG. 9, a memory device 100A is a so-called 1T type organic ferroelectric memory.

More specifically, the memory device 100A has the memory array in which the first signal electrode 101 for selecting a row and the second signal electrode 102 for selecting a column are arranged so as to orthogonally cross each other. A third signal electrode 103 is further arranged so as to pass through around the intersection of the first signal electrode 101 and the second signal electrode 102, and the memory element 1A is coupled there in the memory array.

One of the first signal electrode 101 or the second signal electrode 102 is a word line, and the other is a bit line. Around at each intersection of the first signal electrode 101 and the second signal electrode 102, the first signal electrode 101 is coupled to the drain region 32 and the second signal electrode 102 is coupled to the source region 31. The third signal electrode 103 is coupled to the gate electrode 5B and serves as a writing line for writing data.

Such memory device 100A can perform nondestructive readout.

In terms of the stable operation of the organic ferroelectric memory (memory device), the 2T2C type of 1T1C type organic ferroelectric memory is preferred. However, a 1T type organic ferroelectric memory is preferred in such a light that it is capable of performing the nondestructive readout (NDRO).

Though above-described embodiments mainly describe the memory element according to the invention, the memory element and the manufacturing method thereof according to the embodiments can also be applied to transistors such as a thin film transistor and a manufacturing method thereof. In other words, transistors can be manufactured in the same way as the above-described manufacturing method according to the embodiments. Moreover, it is possible to lower the driving voltage and to improve the response of the transistor.

Where the 1T1C type or 2T2C type memory device is manufactured, a transistor part in the memory array can be formed in the same manner as the memory device according to the embodiment described above. In this way, it is possible to improve the quality of the memory device. Moreover, if a capacitor part in the memory array is manufactured by the method of manufacturing the memory element according to the above-described first embodiment, it is possible to further improve the quality of the memory device.

The memory device 100, 100A described above can be applied to various electronic apparatuses. In this way, it is possible to provide an electronic apparatus in which the driving voltage is lowered even though the crystalline organic ferroelectric material is used to form the ferroelectric layer 4. Moreover, such electronic apparatus is highly reliable because an amount of leakage current is reduced and short circuit is prevented.

Such electronic apparatus includes personal computers, portable information devices and the like.

Though the method for manufacturing a memory element, the method for manufacturing a transistor, the memory element, the memory device and the electronic apparatus according to the invention have been described based on the embodiments with reference to the accompanying drawings, the invention is not limited to the embodiments. The elements and components forming the memory element, the transistor, the memory device and the electric apparatus can be replaced by alternatives having the same functions. Moreover, other elements or components can be further added.

For example, one or more layers can be further provided between the recording layer 4 and the lower electrode 3 and the upper electrode 5 for some purposes. Moreover, one or more layers can be further provided between the recording layer 4C and the semiconductor layer 33 for some purposes.

The transistors in various types of the organic ferroelectric memories including the 2T2C type, the 1T1C type, the CP type and the 1T type can be single-crystal Si transistors, amorphous silicon thin film transistors (a-Si TFTs), low temperature poly silicon TFTs (LTPS TFTs), high temperature poly silicon TFTs (HTPS TFTs) or organic thin film transistors (organic TFTs).

The entire disclosure of Japanese Patent Application No: 2006-156380, filed Jun. 5, 2006 is expressly incorporated by reference herein.

What is claimed is:

1. A method of manufacturing a memory element, comprising:
forming a first electrode over a first face of a substrate;
forming a ferroelectric layer over a second face of the first electrode, the second face being on an opposite side to the substrate side, and the ferroelectric layer including a crystalline organic ferroelectric material; and
forming a second electrode over a third face of the ferroelectric layer, the third face being on an opposite side to the first electrode side, the second electrode being formed by ejecting an vaporized electrode material in a direction inclined with respect to a normal line direction of the substrate and depositing the vaporized electrode material over the third face of the ferroelectric layer.

2. A method of manufacturing a memory element, comprising:
forming a pair of first electrodes with a predetermined space therebetween over a substrate;
forming a semiconductor layer such that the semiconductor layer electrically contacts with both of the first electrodes;
forming a ferroelectric layer over a first face of the semiconductor layer, the first face being on an opposite side to the substrate side, and the ferroelectric layer including a crystalline organic ferroelectric material;
forming a second electrode over a second face of the ferroelectric layer, the second face being on an opposite side to the semiconductor layer side, the second electrode being formed by ejecting an vaporized electrode material in a direction inclined with respect to a normal line direction of the substrate and depositing the vaporized electrode material over the second face of the ferroelectric layer.

3. The method of manufacturing a memory element according to claim 1, an angle θ between the ejecting direction of the vaporized electrode material and the normal line direction of the substrate around the ferroelectric layer being 20-70°.

4. The method of manufacturing a memory element according to claim 1, the substrate being held by a substrate holder from an opposite side to the first face side in such a way that the substrate is inclined with respect to a material source that ejects the vaporized electrode material while the electrode material is ejected from the material source toward the ferroelectric layer formed over the substrate so as to form the second electrode.

5. The method of manufacturing a memory element according to claim 4, the substrate holder rotating or moving around on an axis that extends in a thickness direction of the substrate which is held by the substrate holder.

6. The method of manufacturing a memory element according to claim 4, the substrate holder holding a plurality of substrates.

7. The method of manufacturing a memory element according to claim 6, the substrate holder holding the plurality of the substrates in a same plane which is orthogonal to the axis of the substrate holder and each of the substrates is placed at a same distance from the axis.

8. The method of manufacturing a memory element according to claim 6, the substrate holder rotating or moving each of the substrates around on an axis line that extends from a center of each substrate in a thickness direction of each substrate.

9. The method of manufacturing a memory element according to claim 4, a slit plate having an opening of a slit shape being interposed between the material source and the substrate, the substrate being moved in a shorter direction of the opening of the slit plate while the vaporized electrode material that goes through the opening of the slit plate is deposited on the substrate so as to form the second electrode.

10. The method of manufacturing a memory element according to claim 1, the forming process of the ferroelectric layer further including forming a low-crystalline film having a lower crystallinity than a crystallinity of the finished ferroelectric layer by applying a liquid material containing the organic ferroelectric material over the first electrode and drying the applied liquid material, and
heating the low-crystalline film so as to increase the crystallinity thereof and to form the ferroelectric layer.

11. The method of manufacturing a memory element according to claim 1, the ferroelectric layer having a rough surface on the face where the second electrode is to be formed, the rough surface being made by crystal grains of the organic ferroelectric material, and the ejecting direction of the vaporized electrode material being slanted with respect to the normal direction of the substrate so as to stop or prevent the electrode material from entering into concave portions of the rough surface.

12. A method of manufacturing a transistor, comprising
forming a source region and a drain region with a predetermined space therebetween over a substrate;
forming a semiconductor layer such that the semiconductor layer contacts with both the source region and the drain region;
forming a gate insulating layer over a first face of the semiconductor layer, the first face being on an opposite side to the substrate side, and the gate insulating layer including a crystalline organic ferroelectric material; and
forming a gate electrode over a second face of the gate insulating layer, the second face being on an opposite side to the semiconductor layer side, the gate electrode being formed by ejecting an vaporized electrode material in a direction inclined with respect to a normal line direction of the substrate and depositing the vaporized electrode material on the second face of the gate insulating layer.
